(19) United States
(12) Patent Application Publication
(10) Pub. No.: US 2024/0165668 A1
(43) Pub. Date: May 23, 2024

(54) METHOD FOR PRODUCING A MICRO-ELECTROMECHANICAL VIBRATION SYSTEM

(71) Applicant: Robert Bosch GmbH, Stuttgart (DE)

(72) Inventors: Timo Schary, Aichtal-Neuenhaus (DE); Jan David Brehm, Stuttgart (DE); Johannes Baader, Haslach (DE)

(21) Appl. No.: 18/502,558

(22) Filed: Nov. 6, 2023

(30) Foreign Application Priority Data
Nov. 22, 2022 (DE) 10 2022 212 453.7

(51) Int. Cl. B06B 1/06

(52) U.S. Cl. CPC B06B 1/0666

(57) ABSTRACT

A method for producing a micro-electromechanical vibration system. A carrier substrate is provided. A peripheral first channel extending from a first surface of the carrier substrate at least partially through the carrier substrate, is produced. A passivation layer is applied to the first surface, and the peripheral first channel is at least partially filled with the passivation layer. A first polysilicon layer grows on the passivation layer and/or the first surface of the carrier substrate. A transducer element of the micro-electromechanical vibration system is arranged on a second surface of the first polysilicon layer. A second channel is produced completely through the carrier substrate in the direction of the transducer element. The second channel extends as far as the passivation layer, so that the vibratable transducer plate of the micro-electromechanical vibration system is produced adjacently to the second channel using the first polysilicon layer.

### CROSS REFERENCE

The present application claims the benefit under 35 U.S.C. § 119 of German Patent Application No. DE 10 2022 212 453.7 filed on Nov. 22, 2022, which is expressly incorporated herein by reference in its entirety.

### BACKGROUND INFORMATION

PCT Patent Application No. WO 2016/106153 describes a method for producing a piezoelectric micromachined ultrasonic transducer (PMUT), in which a passivation layer is deposited onto a carrier substrate and is then structured with the desired plate dimensions of the subsequently produced transducer plate of the PMUT sensor. A polysilicon layer is subsequently deposited onto the carrier substrate and/or the passivation layer, and then a transducer element is arranged on its surface. A channel is then produced completely through the carrier substrate by trenching until the polysilicon layer is reached.

In the above-described method from the related art, however, the produced channel has a comparatively wide and flat undercut in the direction of the transducer element.

An object of the present invention is to provide a method for producing a micro-electromechanical vibration system which eliminates the above-mentioned disadvantages from the related art.

### SUMMARY

The present invention may achieve the object by providing a method for producing a micro-electromechanical vibration system, in particular a piezoelectric micromachined ultrasonic transducer.

According to an example embodiment of the present invention, in the method for producing a micro-electromechanical vibration system, a carrier substrate having a first surface is first provided. In particular, the carrier substrate is a silicon substrate, and the micro-electromechanical vibration system is a piezoelectric micromachined ultrasonic transducer. Furthermore, a peripheral first channel, in particular a first trench, is produced. The first channel extends from the first surface of the carrier substrate at least partially through the carrier substrate, and an area of the first surface enclosed by the peripheral first channel has a defined shape and a size. The defined shape and the defined size are preferably a shape and a size, in particular a length, of the transducer plate to be produced as viewed from above. Furthermore, a passivation layer is applied to the first surface of the first carrier substrate, and in the process the first peripheral channel is at least partially filled with the passivation layer. Subsequently, a first polysilicon layer grows on the passivation layer and/or the first surface of the carrier substrate. In particular, the first polysilicon layer grows epitaxially on the passivation layer and/or the first surface of the carrier substrate. In addition, a transducer element of the micro-electromechanical vibration system is arranged on a second surface of the first polysilicon layer. The transducer element is in particular a piezoelectric element. The second surface is in particular aligned substantially in parallel with the first surface of the first carrier substrate. Furthermore, a second channel, in particular second trench, is produced completely through the carrier substrate in the direction of the transducer element. The second channel extends as far as the passivation layer, so that the vibratable transducer plate of the micro-electromechanical vibration system is produced adjacently to the second channel by means of the first polysilicon layer. In the step of producing the second channel, a first trenching step is carried out first, in which a third opening of an, in particular associated, third trench mask has a size, in particular a diameter, which is smaller, in particular significantly smaller, than a size of an area of the transducer plate. The first trenching step is ended before the passivation layer on the first surface is reached, so that a portion of the second channel is left behind or produced. Following the first trenching step, an outer wall, and a bottom face of the portion of the second channel, are provided, in particular completely, with a second etch stop layer. Subsequently, the second etch stop layer is removed on the bottom face of the portion of the second channel, in particular in a region of the portion of the second channel aligned in parallel with the first polysilicon layer. In particular, the second etch stop layer is completely removed on the bottom face. Subsequently, in a subsequent isotropic silicon etching step, the second channel is enlarged, in particular until the passivation layer is reached. The additional application of the second etch stop layer to the outer wall of the produced portion of the second channel improves the protection of the outer wall against undesired etching in the course of the isotropic silicon etching step. In particular, it is thereby made possible to produce a plurality of second channels comparatively close to one another without them being unintentionally connected to one another. Furthermore, in the case of a plurality of adjacently arranged second channels, it is made possible for the process to produce different geometries of the second channels and/or of the produced vibratable transducer plates. Furthermore, a precise definition of the position and the length of the transducer plate to be produced is made possible by the first channel at least partially filled with the second passivation layer. The second etch stop layer is preferably a silicon oxide layer. Alternatively, it is a PE-SiN, ALD AlOx-, polymer or photoresist layer.

According to an example embodiment of the present invention, preferably, the first peripheral channel is closed by the passivation layer, in particular at an upper end of the first channel, during the step of applying the passivation layer.

According to an example embodiment of the present invention, preferably, following application of the passivation layer to the first surface of the carrier substrate, the passivation layer is partially removed by means of a first etching mask in such a way that the passivation layer only remains on a subregion of the first surface, said subregion being enclosed by the first peripheral first channel. In this case, the subregion has, in particular as viewed from above, a shape and an area corresponding to the vibratable transducer plate to be produced. The second channel preferably extends as far as the subregion of the second passivation layer. The area of the first surface enclosed by the peripheral first channel and the contiguous subregion of the passivation layer preferably coincide. In other words, the opening of the first channel is arranged at an outer edge region of the subregion of the second passivation layer.

According to an example embodiment of the present invention, preferably, following the application of the passivation layer to the first surface of the carrier substrate, the passivation layer is removed peripherally by means of a second etching mask in such a way that a third peripheral channel is produced. The third channel extends as far as the first surface of the carrier substrate. The third peripheral channel encloses the first peripheral channel. In a subsequent method step, the first polysilicon layer then grows on the surface of the carrier substrate in the region of the third channel and thus fills the third channel. This third, filled channel can be used later in the method as a lateral stop for an isotropic chemical removal of the passivation layer. The transducer plate can thus still be produced with more exact lateral dimensions. Preferably, the third channel has an oblique or at least partially rounded wall. Local stress peaks of the transducer plate are thus reduced or prevented under load.

According to an example embodiment of the present invention, preferably, the first peripheral channel is produced by trenching in such a way that the first channel has a diameter, in particular a width, in a range of 5 μm to 50 μm at a lower end of the first channel. Preferably, the first channel has a diameter, in particular a width, in a range of 5 μm to 20 μm at the lower end of the first channel. Since the trenching rate falls as the ratio of the depth of the first channel to the width of the first channel increases, this comparatively wide design of the first channel allows a comparatively deep first channel. In order nevertheless to allow a closure of the first channel at the upper end of the first channel and an application of the passivation layer to the wall of the channel, an, in particular outer, wall of the first peripheral channel and a bottom face of the first peripheral channel are coated with a second polysilicon layer or an epi silicon layer, preferably in a method step following the production of the first peripheral channel. Subsequently, in the step of applying the passivation layer to the first surface of the carrier substrate, the first peripheral channel is at least partially filled with the passivation layer, and the first channel is closed by means of the passivation layer. Alternatively, it is preferably provided, in the step of applying the passivation layer, for an, in particular outer, wall of the first peripheral channel to be coated with the passivation layer, and subsequently for the first peripheral channel to be at least partially filled with a second polysilicon layer or an epi silicon layer, and the first channel to be closed by means of the second polysilicon layer or the epi silicon layer. Further alternatively, a grid mask is preferably used as a fourth trench mask for producing the first peripheral channel. Many small grid openings add up to a large lateral mask opening, which allows a deep trench. However, the individual grid openings are small enough to still be closable with technically implementable SiO thicknesses. Subsequently, in the step of applying the passivation layer to the first surface of the carrier substrate, the first peripheral channel is at least partially filled with the passivation layer and closed by means of the passivation layer. All these methods allow a comparatively deep peripheral first channel and thus also a comparatively long region of the first channel, the dimensions, in particular the diameter, of which are laterally delimited and thus determined by the first channel.

According to an example embodiment of the present invention, the passivation layer is preferably used as a first etch stop layer. The passivation layer is preferably in the form of silicon oxide layers.

According to an example embodiment of the present invention, the passivation layer is preferably at least partially removed following the production of the first channel.

The outer wall of the portion of the second channel is preferably cleaned wet-chemically following the first trenching step, and in particular before the second etch stop layer is applied. This results in ideal adhesion properties of the outer wall and the bottom face of the portion of the second channel for the second etch stop layer.

### BRIEF DESCRIPTION OF THE DRAWINGS

FIG. 1 shows a first part of an embodiment of a method for producing a micro-electromechanical vibration system, according to the present invention.

FIG. 2 shows a second part of an embodiment of a method for producing a micro-electromechanical vibration system, according to the present invention.

### DETAILED DESCRIPTION OF EXAMPLE EMBODIMENTS

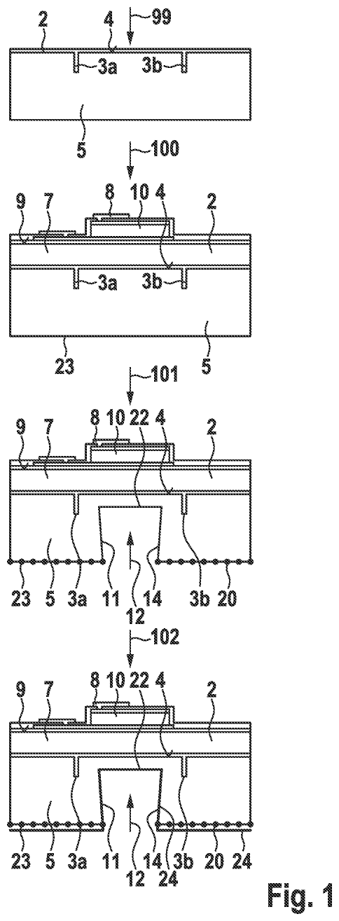

FIG. 1 schematically shows a first part of an embodiment of a method for producing a micro-electromechanical vibration system in the form of a piezoelectric micromachined ultrasonic transducer 120a. In a first method step 99, a carrier substrate 5 having a first surface 4 is provided. The carrier substrate 5 is in the form of a silicon substrate. Furthermore, a first peripheral channel 3a and 3b is produced. The first channel 3a and 3b extends partially through the carrier substrate 5 from the first surface 4 of the carrier substrate 5. An area of the first surface 4 enclosed by the peripheral first channel 3a and 3b has a shape and a size of the vibratable transducer plate 19 of the micro-electromechanical vibration system to be produced later, as viewed from above. Furthermore, a passivation layer 2 is applied to the first surface 4 of the first carrier substrate 5, and the first peripheral channel 3a and 3b is partially filled with the passivation layer 2, and an upper end of the first channel 3a and 3b is closed by means of the passivation layer. The passivation layer 2 is used as a first etch stop layer and in this case is in the form of a silicon oxide layer.

In a subsequent method step 100, a first polysilicon layer 7 grows on the passivation layer 2. Furthermore, a piezoelectric element is arranged as a transducer element 10 on a second surface 9 of the first polysilicon layer 7. The second surface 9 is aligned substantially in parallel with the first surface 4 of the first carrier substrate 5. In addition, the electrical contacting elements 8 of the piezoelectric element are arranged on the first polysilicon layer 7.

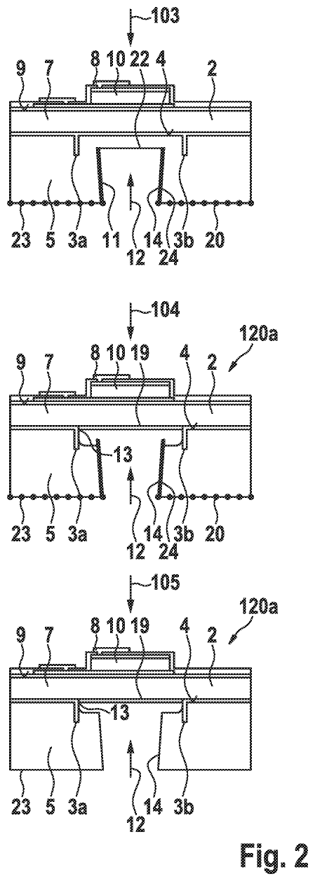

A first trenching step for producing a second channel 14 is shown in a subsequent method step 101. A third trench mask 20, which has a third opening with a size which is significantly smaller than a length of the transducer plate 19 to be produced, is used for this trenching step. The trenching step ends before the passivation layer 2 is reached, and leaves a portion of the second channel 14 behind. In a subsequent method step 102, an outer wall 11 and a bottom face 22 of the portion of the second channel 14 are completely provided with a second etch stop layer 24. In addition, the underside 23 of the carrier substrate 5 is completely provided with the second etch stop layer 24. The second etch stop layer 24 is a silicon oxide layer. In a subsequent method step 103, as shown in FIG. 2, the second etch stop layer 24 is removed on the bottom face 22 of the portion of the second channel 14. In a subsequent method step 104, the second channel 14 is enlarged by means of an isotropic silicon etching step until the passivation layer 2 is reached. The second channel 14 extends as far as the passivation layer 2, so that the vibratable transducer plate 19 of the micro-electromechanical vibration system is produced directly adjacent to the second channel 14 by means of the first polysilicon layer 7. In a further method step 105, the second etch stop layer 24 is removed. Furthermore, the passivation layer 2 is removed at least in the region of the second channel 14.

The second channel has a main extension direction 12 which runs substantially perpendicularly to the first surface 4.

In a further method step (not shown here), the outer wall 11 and the bottom face 22 of the portion of the second channel 14 are cleaned wet-chemically following the first trenching step 101 and before the second etch stop layer 24 is applied.

In a further method step (not shown here), more material of the carrier substrate 5 is removed by means of a grinding process. In this case, the material is removed such that, as far as possible, only the material of the carrier substrate originally enclosed by the first channel remains in place.

What is claimed is:

1. A method for producing a micro-electromechanical vibration system including a piezoelectric micromachined ultrasonic transducer, the method comprising the following steps:
providing a carrier substrate having a first surface; and
producing a peripheral first channel including a first trench, wherein the peripheral first channel extends from the first surface of the carrier substrate at least partially through the carrier substrate, wherein an area of the first surface enclosed by the peripheral first channel has a defined shape and a size of a vibratable transducer plate to be produced of the micro-electromechanical vibration system, as viewed from above;
applying a passivation layer to the first surface of the first carrier substrate, wherein the peripheral first channel is at least partially filled with the passivation layer;
epitaxially growing a first polysilicon layer on the passivation layer and/or the first surface of the carrier substrate;
arranging a transducer element of the micro-electromechanical vibration system, including of a piezoelectric element of the piezoelectric micromachined ultrasonic transducer, on a second surface of the first polysilicon layer, wherein the second surface is aligned substantially in parallel with the first surface of the first carrier substrate; and
producing a second channel including a second trench, completely through the carrier substrate in a direction of the transducer element, wherein the second channel extends as far as the passivation layer, so that the vibratable transducer plate of the micro-electromechanical vibration system is produced adjacently to the second channel using the first polysilicon layer;
wherein, in the step of producing the second channel, a first trenching step is carried out first, in which a third opening of an associated third trench mask has a size including a diameter, which is smaller, than a size of an area of the transducer plate, wherein the first trenching step is ended before the passivation layer on the first surface is reached, and leaves behind a portion of the second channel, wherein, following the first trenching step, an outer wall and a bottom face of the portion of the second channel are provided completely with a second etch stop layer, and subsequently the second etch stop layer is removed on the bottom face of the portion of the second channel, in a region of the portion of the second channel aligned in parallel with the first polysilicon layer, and the second channel is enlarged until the passivation layer is reached, in a subsequent isotropic silicon etching step.

2. The method according to claim 1, wherein the peripheral first channel is closed by the passivation layer at an upper end of the peripheral first channel, during the step of applying the passivation layer.

3. The method according to claim 1, wherein following application of the passivation layer to the first surface of the carrier substrate, the passivation layer is partially removed using a first etching mask in such a way that the passivation layer remains only on a subregion of the first surface, the subregion being enclosed by the peripheral first channel.

4. The method according to claim 1, wherein following application of the passivation layer to the first surface of the carrier substrate, the passivation layer is removed peripherally using a second etching mask in such a way that a third peripheral channel is produced, wherein the third channel extends as far as the first surface of the carrier substrate, wherein the third peripheral channel encloses the first peripheral channel.

5. The method according to claim 1, wherein the peripheral first channel is produced by trenching in such a way that the peripheral first channel has a diameter in a range of 5 μm to 50 μm at a lower end of the peripheral first channel.

6. The method according to claim 5, wherein the range is 5 μm to 20 μm.

7. The method according to claim 5, wherein an outer wall of the peripheral first channel and a bottom face of the peripheral first channel is coated with a second polysilicon layer or an epi silicon layer following the production of the peripheral first channel, and subsequently the peripheral first channel is at least partially filled with the passivation layer during the step of applying the passivation layer to the first surface of the carrier substrate.

8. The method according to claim 5, wherein an outer wall of the peripheral first channel is coated with the passivation layer during the step of applying the passivation layer, and subsequently the peripheral first channel is filled at least partially with a second polysilicon layer or an epi silicon layer.

9. The method according to claim 5, wherein a grid mask is used as a fourth trench mask to produce the peripheral first channel, wherein the peripheral first channel is then at least partially filled with the passivation layer and the peripheral first channel is closed using the passivation layer during the step of applying the passivation layer to the first surface of the carrier substrate.

10. The method according to claim 1, wherein the passivation layer is used as a first etch stop layer.

11. The method according to claim 1, wherein the passivation layer is a silicon oxide layer.

12. The method according to claim 1, characterized in that the outer wall and the bottom face of the portion of the second channel are cleaned wet-chemically following the first trenching step, and before the second etch stop layer is applied.
